(19) United States
(12) Patent Application Publication
(10) Pub. No.: US 2026/0121606 A1
(43) Pub. Date: Apr. 30, 2026

(54) MULTI-BAND WIRELESS COMMUNICATION DEVICE AND METHOD FOR TRANSMITTING MULTI-BAND WIRELESS COMMUNICATION SIGNALS

(71) Applicant: MEDIATEK INC., Hsinchu City (TW)

(72) Inventors: Wei-Chia Chan, Hsinchu City (TW); Tzung-Chuen Tsai, Hsinchu City (TW); Hui-Hsien Liu, Hsinchu City (TW); Yuan-Hung Chung, Hsinchu City (TW)

(73) Assignee: MEDIATEK INC., Hsinchu City (TW)

(21) Appl. No.: 19/008,553

(22) Filed: Jan. 2, 2025

Related U.S. Application Data
(60) Provisional application No. 63/617,103, filed on Jan. 3, 2024.

(51) Int. Cl. H03H 7/42; H03F 3/24; H04B 1/04

(52) U.S. Cl. CPC H03H 7/42; H03F 3/245; H04B 1/0483; H03F 2200/451

(57) ABSTRACT

A multi-band wireless communication device and a method for transmitting multi-band wireless communication signals are provided. The multi-band wireless communication device includes a wireless communication chip, an external power amplifier and an external converting circuit, where both the external power amplifier and the external converting circuit are placed outside the wireless communication chip. A first transmitting path circuit is configured to output a first output signal of a first band. A second transmitting path circuit is configured to output a pair of differential signals of a second band. The external power amplifier is configured to amplify the first output signal to generate a first transmitted signal of the first band, and the external converting circuit is configured to convert the pair of differential signals into a second transmitted signal of the second band, wherein the second transmitted signal is a single-ended signal.

### CROSS REFERENCE TO RELATED APPLICATIONS

This application claims the benefit of U.S. Provisional Application No. 63/617,103, filed on Jan. 3, 2024. The content of the application is incorporated herein by reference.

### BACKGROUND

The present invention is related to wireless communication devices, and more particularly, to a multi-band wireless communication device and a method for transmitting multi-band wireless communication signals.

In world-wide wireless communication specification specified by Federal Communications Commission (FCC), there are some limitations to spectrum behaviors when transmitting signals. For example, FCC requests that energy of an interference in signals needs to be lower than specific value when transmitting/receiving the signals in an operation band. However, meeting the requirements mentioned above can be challenging for multi-band transmission under some conditions.

Thus, there is a need for a novel architecture and an associated method, which enable the multi-band transmission to meet target specification without introducing any side effects or in a way that is less likely to introduce side effects.

### SUMMARY

An objective of the present invention is to provide a multi-band wireless communication device and a method for transmitting multi-band wireless communication signals, which enable transmitted signals of the multi-band wireless communication device to conform to FCC regulation without greatly increasing additional costs.

At least one embodiment of the present invention provides a multi-band wireless communication device. The multi-band wireless communication device comprises a wireless communication chip, an external power amplifier and an external converting circuit, where both the external power amplifier and the external converting circuit are placed outside the wireless communication chip. The wireless communication chip comprises a first transmitting path circuit and a second transmitting path circuit, where the first transmitting path circuit is configured to output a first output signal of a first band, and the second transmitting path circuit is configured to output a pair of differential signals of a second band that is different from the first band. The external power amplifier is coupled to the first transmitting path circuit, and is configured to amplify the first output signal of the first band to generate a first transmitted signal of the first band. The external converting circuit is coupled to the second transmitting path circuit, and is configured to convert the pair of differential signals of a second band into a second transmitted signal of the second band, wherein the second transmitted signal of the second band is a single-ended signal.

At least one embodiment of the present invention provides a method for transmitting multi-band wireless communication signals. The method comprises: utilizing a first transmitting path circuit integrated inside a wireless communication chip to output a first output signal of a first band; utilizing an external power amplifier (PA) placed outside the wireless communication chip to amplify the first output signal of the first band to generate a first transmitted signal of the first band; utilizing a second transmitting path circuit integrated inside the wireless communication chip to output a pair of differential signals of a second band that is different from the first band; and utilizing an external converting circuit placed outside the wireless communication chip to convert the pair of differential signals of a second band into a second transmitted signal of the second band, wherein the second transmitted signal is a single-ended signal.

The multi-band wireless communication device and the method provided by the embodiments of the present invention place the converting circuit such as a balanced-to-unbalanced (balun) transformer or inductor and capacitor components at outside of the wireless communication chip, instead of implementing the converting circuit by an on-chip balun (which is implemented by on-chip inductive coils). Thus, interference and coupling introduced inside the wireless communication chip can be reduced or eliminated, thereby preventing second-order or third-order harmonic interference of the pair of differential signals in the first transmitted signal of the first band from exceeding acceptable level due to amplification of the external PA. In addition, the embodiments of the present invention will not greatly increase additional costs. Thus, the present invention can enable the transmitted signals output from the multi-band wireless communication device to conform to FCC regulation without introducing any side effects or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a multi-band wireless communication device according to an embodiment of the present invention.

FIG. 2 is a diagram illustrating a multi-band wireless communication device according to another embodiment of the present invention.

FIG. 3 is a diagram illustrating a working flow of a method for transmitting multi-band wireless communication signals according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”.

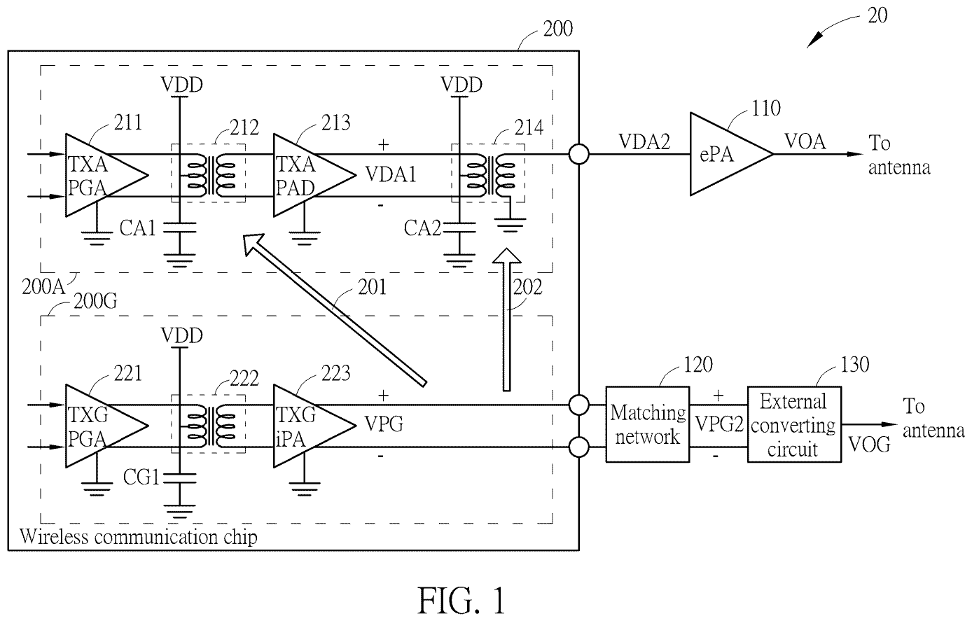

FIG. 1 is a diagram illustrating a multi-band wireless communication device 20 according to an embodiment of the present invention. As shown in FIG. 1, the multi-band wireless communication device 20 may comprise a wireless communication chip 200, an external power amplifier (PA) 110 (labeled “ePA” in figures for brevity), a matching network 120 and an external converting circuit 130, which may be located on a PCB (Printed Circuit Board). The wireless communication chip 200 may comprise a first transmitting path circuit such as an A-band transmitting path circuit 200A and a second transmitting path circuit such as a G-band transmitting path circuit 200G, where the external PA 110 is coupled to the A-band transmitting path circuit 200A, and the matching network 120 and external converting circuit 130 are coupled to the G-band transmitting path circuit 200G. In this embodiment, the A-band transmitting path circuit 200A and the external PA 110 are configured to output a transmitted signal VOA to an antenna, and the G-band transmitting path circuit 200G, the matching network 120 and the external converting circuit 130 are configured to output a transmitted signal VOG to an antenna, where the transmitted signal VOA may be carried at an A-band such as a 5-gigahertz (GHz) band or a 6-GHz band, and the transmitted signal VOG may be carried at a G-band such as a 2.4-GHz band.

The A-band transmitting path circuit 200A may comprise a programmable gain amplifier (PGA) 211 (labeled “TXA PGA” in figures for better comprehension), an impedance transformer 212 (which may be implemented by inductive coils) connected to a reference voltage VDD, a PA driver 213 (labeled “TXA PAD” in figures for better comprehension), a balanced-to-unbalanced (balun) transformer 214 (which may be implemented by inductive coils) connected to the reference voltage VDD, and capacitors CA1 and CA2. The PGA 211 is configured to receive first differential signals of the A-band, and amplify the first differential signals to generate amplified first differential signals of the A-band. The impedance transformer 212 is coupled between the PGA 211 and the PA driver 213, and is configured to provide an impedance match between PGA 211 and the PA driver 213, where the impedance transformer 212 receives the amplified first differential signals and accordingly output second differential signals. The PA driver 213 is configured to receive the second differential signals, and amplify the second differential signals to generate amplified second differential signal (which may be represented by an output signal VDA1). The balun transformer 214 is coupled between the PA driver 213 and the external PA 110, and is configured to convert the second differential signals into a first output signal (which may be represented by an output signal VDA2), where the first output signal is a single-ended signal. In some embodiment, the PGA 211 and the impedance transformer 212 may be omitted, where the first differential signals mentioned above may be received by the PA driver 213. In some embodiment, the impedance transformer 212 and the PA driver 213 may be omitted, where the amplified first differential signals output from the PGA 211 may be transmitted to the balun transformer 214. In some embodiments, the PGA 211, the impedance transformer 212 and the PA driver 213 may be omitted, where the first differential signals may be received by the balun transformer 214.

The G-band transmitting path circuit 200G may comprise a PGA 221 (labeled “TXG PGA” in figures for better comprehension), an impedance transformer 222 (which may be implemented by inductive coils) connected to the reference voltage VDD and an internal PA 223 (labeled “TXG iPA” in figures for better comprehension). The PGA 221 is configured to receive first differential signals of the G-band, and amplify the first differential signals of the G-band to generate amplified first differential signals of the G-band. The impedance transformer 222 is coupled between the PGA 221 and the PA 223, and is configured to provide an impedance match between PGA 221 and the PA 223, where the impedance transformer 222 receives the amplified first differential signals of the G-band and accordingly output second differential signals of the G-band. The PA 223 is configured to receive the second differential signals of the G-band, and amplify the second differential signals of the G-band to generate amplified second differential signals (which may be represented by an output signal VPG). In some embodiments, the PGA 221 and the impedance transformer 222 may be omitted, where the first differential signals of the G-band may be received by the internal PA 223.

The A-band may be a 5G band or a 6G band. The internal PA 223 (which is integrated in the wireless communication chip 200) is typically a main source of non-linear effects, and therefore generates second-order and third-order harmonic interferences on an output thereof (e.g. the output signal VPG, which is a pair of differential signals), where a main signal within the output signal VPG is at the G-band (e.g. a frequency range of G-band may be 2.412 GHz to 2.472 GHz), and the second-order harmonic interference within the output signal VPG may be at a frequency segment, which partially overlaps the 5G band (e.g. a frequency range of the 5G band may be at 5.180 GHz to 5.850 GHz) or is very close to the lowest frequency of the 5G band, and the third-order harmonic interference within the output signal VPG may be at a frequency segment, which partially overlaps the 6G band (e.g. a frequency range of 6G band may be at 5.925 GHz to 7.115 GHz) or is very close to the highest frequency of the 6G band. In some embodiment, the A-band may comprise the 5G band and the 6G band.

During the design process of the multi-band wireless communication device, the inventors discovered that if a transformer with inductive coils is located in the wireless communication chip 200 and coupled to the output of the internal PA 223, because impedance transformer 212 and the balun transformer 214 are implemented by inductive coils, the second-order harmonic interference or the third-order harmonic interference on the transformer coupled to the output of the internal PA 223 may be coupled to the impedance transformer 212 and the balun transformer 214 through coupling. In addition, components within the A-band transmitting path circuit 200A and the external PA 110 are design for transmitting signals of the A-band, and therefore the second-order harmonic interference (which falls in a frequency range of the A-band or is very close the lowest frequency of the A-band) or the third-order harmonic interference (which falls in a frequency range of the A-band or is very close the highest frequency of the A-band) from the G-band transmitting path circuit 200G may be transmitted through the PA driver 213, the balun transformer 214 and the external PA 110. Thus, the second-order harmonic interference or the third-order harmonic interference from the G-band transmitting circuit 200G (more particularly, from the output of the internal PA 223) may occur in the output signal VDA1 (which is a pair of differential signals) of the PA driver 213, the output signal VDA2 (which is generated by converting the output signal VDA1 into a single-ended signal) of the balun transformer 214 and the transmitted signal VOA (which is generated by amplifying the output signal VDA2) output from the external PA 110. Furthermore, the external PA 110 typically provides a gain substantially equal to 30 decibel (dB), and therefore amplifies the second-order harmonic interference or the third-order harmonic interference within the output signal VDA2. Under this condition, when the multi-band wireless communication device 20 needs to meet requirements of emission specification, design of the wireless communication chip 200 may be challenging. For example, when power of the second-order harmonic interference or the third-order harmonic interference within the transmitted signal VOA needs to be lower than −48 decibel relative to one milliwatt (dBm) in order to meet the requirements of emission specification, the power of the second-order harmonic interference or the third-order harmonic interference within the output signal VDA2 needs to be lower than −78 dBm as the external PA 110 provide a 30 dB gain, making target performance of the wireless communication chip 200 hard to be reached. In some embodiment, the power of the output signal VPG can be reduced in order to reduce the power of the second-order harmonic or the third-order harmonic generated by the internal PA 223, and one or more notch filter can be placed at an input and/or an output of the external PA 110 regarding the frequency of the second-order harmonic interference or the third-order harmonic interference, thereby reducing the power of the second-order harmonic interference or the third-order harmonic interference within the output signal VDA2 and the transmitted signal VOA. However, this solution makes transmitting performance of the G-band degrades, and on-board costs may be greatly increased due to the notch filter(s).

Thus, the present invention is aimed at preventing any inductive coil at the output of the internal PA 223, in order to prevent or reduce the second-order harmonic interference or the third-order harmonic interference on the output of the internal PA 223 from being coupled to the impedance transformer 212 (as indicated by an interference signal 201 shown in FIG. 1) and the balun transformer 214 (as indicated by an interference signal 202 shown in FIG. 1) through coupling.

In order to prevent the output signal VPG from being transmitted through any on-chip transformer which comprise inductive coil(s), the multi-band wireless communication device 20 may further comprise a matching network 120 and an external converting circuit 130, where the external converting circuit 130 is coupled to the G-band transmitting path circuit 200G through the matching network 120. Under this configuration, the output signal VPG is transmitted through trace(s), which may prevent or reduce the second-order harmonic interference or the third-order harmonic interference within the output signal VPG from being transmitted (e.g. coupling) to the impedance transformer 212 and the balun transformer 214. In this embodiment, the A-band transmitting path circuit 200A is configured to output a first output signal such as the output signal VDA2, and the G-band transmitting path circuit 200G is configured to output a second output signal such as the output signal VPG. The external PA 110 is placed outside the wireless communication chip 200, and is configured to amplify the output signal VDA2 to generate a first transmitted signal of a first band, such as the transmitted signal VOA of the A-band. The external converting circuit 130 is placed outside the wireless communication chip 200, and is configured to generate a second transmitted signal of a second band, such as the transmitted signal VOG of the G-band, according to the output signal VPG, where the output signal VPG is a pair of differential signals, and the transmitted signal VOG is a single-ended signal.

As mentioned above, the multi-band wireless communication device 20 may further comprise the matching network 120, where the matching network 120 is coupled to the G-band transmitting path circuit 200G and the external converting circuit 130. In this embodiment, the matching network 120 is placed outside the wireless communication chip, and is configured to provide an impedance match between an output impedance of the internal PA 223 and an input impedance of the external converting circuit 130, where the matching network 120 is configured to receive the output signal VPG (which is transmitted from an on-chip device such as the internal PA 223) and accordingly output an output signal VPG2 to the external converting circuit. In some embodiment, the external converting circuit may comprise an embedded input matching network for receiving the output signal VPG, so that the matching network 120 may be omitted, but the present invention is not limited thereto.

In this embodiment, there is not any on-chip balun transformer (which may comprise inductive coil(s) introducing the issues related to the second-order harmonic interference or the third-order harmonic interference mentioned above) placed at the output of the internal PA 223. More particularly, tasks of the on-chip balun transformer are executed by the external converting circuit 130. The external converting circuit 130 may be a balun transformer. In one embodiment, the balun transformer may be a co-fired ceramic balun transformer such as a low temperature co-fired ceramic (LTCC) balun transformer (e.g. a co-fired ceramic balun transformer fabricated under a sintering temperature lower than 1000° C.). In particular, a typical package of the LTCC balun transformer may comprises multiple terminals such as an unbalanced port (which is coupled to the antenna), a ground port (which may be coupled to a ground voltage), a reference port (which may be coupled to the ground voltage, a direct current (DC) feed voltage or a radio frequency (RF) ground voltage), a first balanced port (which is coupled to a first output terminal of the internal PA 223 or a first output terminal of the matching network 120), a floating port (which has no connection to outside of the package) and a second balanced port (which is coupled to a second output terminal of the internal PA 223 or a second output terminal of the matching network 120). In some embodiment, the reference port and the floating port may be omitted. It should be noted that fabrication and a structure of the LTCC balun transformer are well-known by those skilled in this art, and related details are omitted here for brevity. An embedded input matching network may be integrated into the balun transformer. Under this condition, the matching network 120 and the external converting circuit 130 are integrated together as the balun transformer.

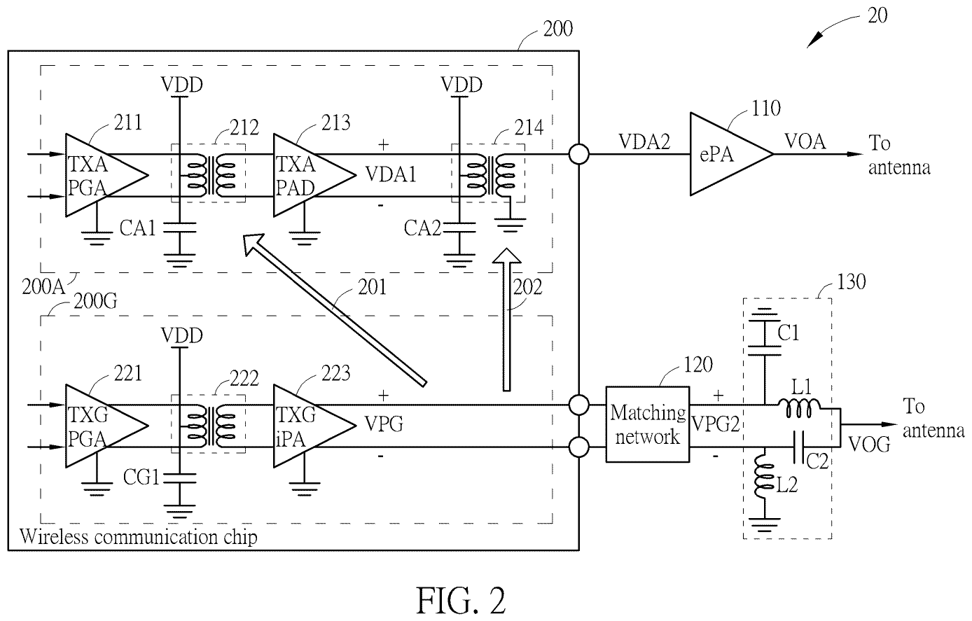

In another embodiment, the external converting circuit 130 may comprise external capacitors C1 and C2 and external inductors L1 and L2, as shown in FIG. 2. The capacitor C1 is coupled to a first output terminal of the matching network 120 (or a first output terminal of the internal PA 223) in shunt, and the inductor L1 is coupled between the first output terminal of the matching network 120 (or the first output terminal of the internal PA 223) and the antenna in series. The inductor L2 is coupled to a second output terminal of the matching network 120 (or a second output terminal of the internal PA 223) in shunt, and the capacitor C2 is coupled between the second output terminal of the matching network 120 (or the second output terminal of the internal PA 223) and the antenna in series. In addition, other converting circuits, which can convert the output voltage VPG from the internal PA 223 or the output voltage VPG2 from the matching network 120 into a single-ended signal such as the transmitted signal VOG, may be alternative designs of the external converting circuit 130. As long as the external converting circuit 130 is able to perform a differential to single end conversion and is placed outside the wireless communication chip 200, these alternative designs should fall in the scope of the present invention.

As shown in FIG. 1, the output signal VPG is transmitted to outside of the wireless communication chip 200 through trace(s) rather than an on-chip balun transformer with inductive coils, coupling effects from output of the internal PA 223 to the impedance transformer 212 or the balun transformer 214 can be greatly reduced. Thus, the second-order harmonic interference or the third-order harmonic interference transmitted to the impedance transformer 212 (as indicated by the interference signal 201) or the balun transformer 214 (as indicated by the interference signal 202) through coupling can be greatly reduced or eliminated. Thus, the multi-band wireless communication device 20 shown in FIG. 1 does not need to sacrifice the transmission performance of the G-band, and the notch filter(s) mentioned above can be omitted.

In addition, some components, which are generally included in a transceiver or a transmitter, are not shown in FIG. 1, where operations and implementations of these components applied to the multi-band wireless communication device 20 should be well-known by those skilled in this art, and related details are omitted here for brevity.

The embodiments of the present invention may be applied in Dual Band Dual Concurrent (DBDC) operation. It should be noted that two bands (G-band and A band) are for illustrative purposes only, and is not meant to be a limitation of the present invention.

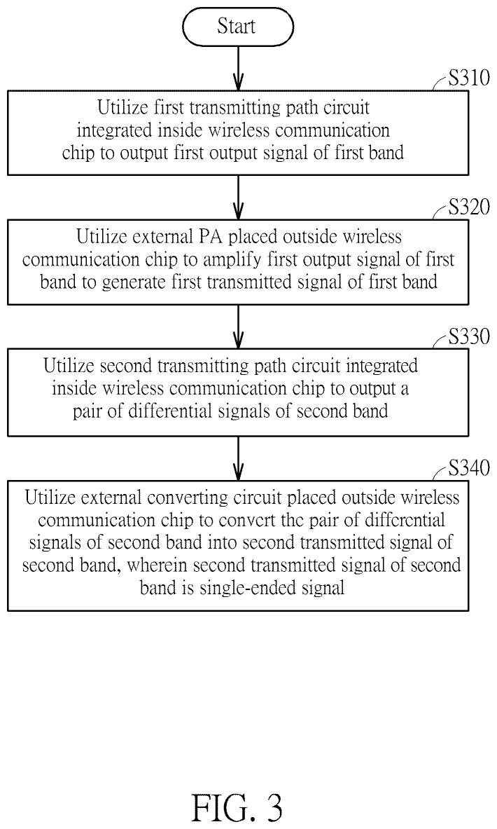

FIG. 3 is a diagram illustrating a working flow of a method for transmitting multi-band wireless communication signals according to an embodiment of the present invention, where the working flow shown in FIG. 3 may be executed by the multi-band wireless communication device 20. It should be noted that the working flow shown in FIG. 3 is for illustrative purposes only, and is not meant to be a limitation of the present invention. For example, one or more steps may be added, deleted or modified in the working flow shown in FIG. 3. In addition, if a same result can be obtained, these steps do not have to be executed in the exact order shown in FIG. 3.

In Step S310, the multi-band wireless communication device 20 may utilize a first transmitting path circuit (e.g. the A-band transmitting path circuit 200A) integrated inside the wireless communication chip 200 to output a first output signal (e.g. the output signal VDA2) of a first band.

In Step S320, the multi-band wireless communication device 20 may utilize the external PA 110 placed outside the wireless communication chip 200 to amplify the first output signal of the first band to generate a first transmitted signal of the first band (e.g. the transmitted signal VOA of the A-band).

In Step S330, the multi-band wireless communication device 20 may utilize a second transmitting path circuit (e.g. the G-band transmitting path circuit 200G) integrated inside the wireless communication chip 200 to output a pair of differential signals (e.g. the output signal VPG) of a second band.

In Step S340, the multi-band wireless communication device 20 may utilize an external converting circuit (e.g. the external converting circuit 130) placed outside the wireless communication chip 200 to convert the pair of differential signals of a second band into a second transmitted signal of the second band (e.g. the transmitted signal VOG of the G-band), wherein the second transmitted signal of the second band is a single-ended signal.

In some embodiments, the first output signal is output from an internal balanced-to-unbalanced (balun) transformer within the first transmitting path circuit, and the pair of differential signals are output from an internal PA within the second transmitting path circuit. In some embodiments, the multi-band wireless communication device 20 may utilize a matching network coupled between the second transmitting path circuit and the external converting circuit and placed outside the wireless communication chip to provide an impedance match. For example, the multi-band wireless communication device 20 may utilize the matching network to provide an impedance match between an output impedance of the internal PA and an input impedance of the external converting circuit.

To summarized, the embodiments of the present invention place the component for differential to single-ended conversion at outside of the wireless communication chip 200, to thereby prevent or reduce the output signal VPG of the internal PA 223 from being coupled to any on-chip inductive coil in the A-band transmitting path circuit. Thus, coupling of the second-order harmonic interference to components within the A-band transmitting path circuit 200A can be reduced. With the architecture of the multi-band wireless communication device 20, the emission specification can be met without reducing output power of the internal PA 223, and additional notch filter(s) are not required. Thus, the embodiment of the present invention can enable the transmitted signals VOA and VOG output from the multi-band wireless communication device 20 to conform to FCC regulation without introducing any side effects or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multi-band wireless communication device, comprising:
a wireless communication chip, comprising:
a first transmitting path circuit, configured to output a first output signal of a first band; and
a second transmitting path circuit, configured to output a pair of differential signals of a second band that is different from the first band;
an external power amplifier, coupled to the first transmitting path circuit, placed outside the wireless communication chip, configured to amplify the first output signal to generate a first transmitted signal of the first band; and
an external converting circuit, coupled to the second transmitting path circuit, placed outside the wireless communication chip, configured to convert the pair of differential signals into a second transmitted signal of the second band, wherein the second transmitted signal is a single-ended signal.

2. The multi-band wireless communication device of claim 1, wherein the first output signal is output from an internal balanced-to-unbalanced (balun) transformer within the first transmitting path circuit, and the pair of differential signals are output from an internal power amplifier (PA) within the second transmitting path circuit.

3. The multi-band wireless communication device of claim 2, further comprising:
a matching network, coupled between the second transmitting path circuit and the external converting circuit, placed outside the wireless communication chip, configured to provide an impedance match.

4. The multi-band wireless communication device of claim 3, wherein the matching network and the external converting circuit are integrated together as a balun transformer.

5. The multi-band wireless communication device of claim 1, wherein the external converting circuit is a balanced-to-unbalanced (balun) transformer or a converting circuit implemented by external capacitors and external inductors.

6. The multi-band wireless communication device of claim 5, wherein the balun transformer is a co-fired ceramic balun transformer.

7. The multi-band wireless communication device of claim 2, wherein the pair of differential signals are transmitted through a trace within the second transmitting path circuit, and no balun transformer is located in a transmission path of the pair of differential signals within the second transmitting path circuit in the wireless communication chip.

8. The multi-band wireless communication device of claim 2, wherein the internal balun transformer is a differential to single-ended converter, wherein the internal balun transformer is configured to receive a pair of differential signals of the first band, and convert the pair of differential signals of the first band into a single ended signal of the first band.

9. The multi-band wireless communication device of claim 1, wherein the first band is a 5G band or a 6G band and the second band is a 2.4G band.

10. The multi-band wireless communication device of claim 2, wherein a second-order or third-order harmonic of the pair of differential signals of the second band is prevented from coupled to the internal balun transformer.

11. A method for transmitting multi-band wireless communication signals, comprising:
utilizing a first transmitting path circuit integrated inside a wireless communication chip to output a first output signal of a first band;
utilizing an external power amplifier (PA) placed outside the wireless communication chip to amplify the first output signal to generate a first transmitted signal of the first band;
utilizing a second transmitting path circuit integrated inside the wireless communication chip to output a pair of differential signals of a second band that is different from the first band; and
utilizing an external converting circuit placed outside the wireless communication chip to convert the pair of differential signals into a second transmitted signal of the second band, wherein the second transmitted signal is a single-ended signal.

12. The method of claim 11, wherein the first output signal is output from an internal balanced-to-unbalanced (balun) transformer within the first transmitting path circuit, and the pair of differential signals are output from an internal PA within the second transmitting path circuit.

13. The method of claim 12, further comprising:
utilizing a matching network coupled between the second transmitting path circuit and the external converting circuit and placed outside the wireless communication chip to provide an impedance match.

14. The method of claim 13, wherein the matching network and the external converting circuit are integrated together as a balun transformer.

15. The method of claim 11, wherein the external converting circuit is a balanced-to-unbalanced (balun) transformer or a converting circuit implemented by external capacitors and external inductors.

16. The method of claim 15, wherein the balun transformer is a co-fired ceramic balun transformer.

17. The method of claim 11, wherein the pair of differential signals are transmitted through a trace within the second transmitting path circuit, and no balun transformer is located in a transmission path of the pair of differential signals within the second transmitting path circuit in the wireless communication chip.
